(19) United States
(12) Patent Application Publication
(10) Pub. No.: US 2018/0102772 A1
(43) Pub. Date: Apr. 12, 2018

(54) DUTY CYCLE CONTROL BUFFER CIRCUIT

(71) Applicant: QUALCOMM Incorporated, San Diego, CA (US)

(72) Inventors: Animesh PAUL, Bangalore (IN); Xinhua CHEN, San Diego, CA (US)

(21) Appl. No.: 15/290,484

(22) Filed: Oct. 11, 2016

(51) Int. Cl. H03K 5/156; H03K 5/134

(52) U.S. Cl. CPC H03K 5/1565; H04B 1/40; H03K 5/134

(57) ABSTRACT

Certain aspects of the present disclosure generally relate to generating clock signals. For example, certain aspects of the present disclosure provide a multi-stage clock generation circuit. The multi-stage clock generation circuit generally includes a first clock-generation stage comprising first cascode-connected transistors the first cascode-connected transistors having gates coupled to a first input clock node. The multi-stage clock generation circuit may also include a second clock-generation stage comprising second cascode-connected transistors, the second cascode-connected transistors having gates coupled to a second input clock node. A first transistor may be coupled to the second cascode-connected transistors, the first transistor having a gate coupled to drains of the first cascode-connected transistors.

### TECHNICAL FIELD

Certain aspects of the present disclosure generally relate to electronic circuits and, more particularly, to a circuit for generating a clock signal.

### BACKGROUND

Wireless communication networks are widely deployed to provide various communication services such as telephony, video, data, messaging, broadcasts, and so on. Such networks, which are usually multiple access networks, support communications for multiple users by sharing the available network resources. For example, one network may be a 3G (the third generation of mobile phone standards and technology) system, which may provide network service via any one of various 3G radio access technologies (RATs) including EVDO (Evolution-Data Optimized), 1×RTT (1 times Radio Transmission Technology, or simply 1×), W-CDMA (Wideband Code Division Multiple Access), UMTS-TDD (Universal Mobile Telecommunications System—Time Division Duplexing), HSPA (High Speed Packet Access), GPRS (General Packet Radio Service), or EDGE (Enhanced Data rates for Global Evolution). The 3G network is a wide area cellular telephone network that evolved to incorporate high-speed internet access and video telephony, in addition to voice calls. Furthermore, a 3G network may be more established and provide larger coverage areas than other network systems. Such multiple access networks may also include code division multiple access (CDMA) systems, time division multiple access (TDMA) systems, frequency division multiple access (FDMA) systems, orthogonal frequency division multiple access (OFDMA) systems, single-carrier FDMA (SC-FDMA) networks, 3^{rd} Generation Partnership Project (3GPP) Long Term Evolution (LTE) networks, and Long Term Evolution Advanced (LTE-A) networks.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station.

MSs and BSs may generate one or more clock signals to be used in receiving and/or transmitting signals. For example, clock signals (e.g., local oscillator signals) may be used to upconvert signals for transmission and/or downconvert received signals. These operations may be performed via one or more mixers and frequency divider circuits.

### SUMMARY

Certain aspects of the present disclosure generally relate to generating clock signals.

Certain aspects of the present disclosure provide a multi-stage clock-generation circuit. The multi-stage clock generation circuit generally includes a first clock-generation stage comprising first cascode-connected transistors the first cascode-connected transistors having gates coupled to a first input clock node, and a second clock-generation stage comprising second cascode-connected transistors, the second cascode-connected transistors having gates coupled to a second input clock node, and a first transistor coupled to the second cascode-connected transistors, the first transistor having a gate coupled to drains of the first cascode-connected transistors.

Certain aspects of the present disclosure provide a duty-cycle control circuit. The duty-cycle control circuit generally includes first cascode-connected transistors having gates coupled to a first input clock node, second cascode-connected transistors having gates coupled to drains of the first cascode-connected transistors, and a transistor coupled to the first cascode-connected transistors.

Certain aspects of the present disclosure provide a method for clock signal generation. The method generally includes receiving a first input clock signal at gates of first cascode-connected transistors of a first clock-generation stage, generating a first biasing signal at drains of the first cascode-connected transistors, receiving a second input clock signal at gates of second cascode-connected transistors of a second clock-generation stage, biasing with the first biasing signal a gate of a first transistor coupled to the second cascode-connected transistors, and generating a first output clock signal based on the second input clock signal and the first biasing signal.

Certain aspects of the present disclosure provide a method for controlling a duty cycle of an output clock signal. The method generally includes receiving a biasing signal at a gate of a transistor coupled to first cascode-connected transistors, receiving an input clock signal at gates of the first cascode-connected transistors, generating the output clock signal based on the input clock signal, and controlling the duty cycle of the output clock signal via the second biasing signal.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in accordance with certain aspects of the present disclosure.

FIG. 2 is a block diagram of an example access point (AP) and example user terminals, in accordance with certain aspects of the present disclosure.

FIG. 3 is a block diagram of an example transceiver front end, in accordance with certain aspects of the present disclosure.

FIG. 4 illustrates an example duty cycle control (DTC) buffer stage, in accordance with certain aspects of the present disclosure.

FIG. 5 illustrates an example clock generation circuit implemented with the DTC buffer stage of FIG. 4, in accordance with certain aspects of the present disclosure.

FIG. 6 illustrates a direct-current (DC) coupled DTC buffer stage, in accordance with certain aspects of the present disclosure.

FIG. 7 illustrates a DTC buffer stage combining the aspects of FIG. 4 and FIG. 6, in accordance with certain aspects of the present disclosure.

FIG. 8 is a flow diagram of example operations for clock signal generation, in accordance with certain aspects of the present disclosure.

FIG. 9 is a flow diagram of example operations for controlling a duty cycle of an output clock signal, in accordance with certain aspects of the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

The techniques described herein may be used in combination with various wireless technologies such as Code Division Multiple Access (CDMA), Orthogonal Frequency Division Multiplexing (OFDM), Time Division Multiple Access (TDMA), Spatial Division Multiple Access (SDMA), Single Carrier Frequency Division Multiple Access (SC-FDMA), Time Division Synchronous Code Division Multiple Access (TD-SCDMA), and so on. Multiple user terminals can concurrently transmit/receive data via different (1) orthogonal code channels for CDMA, (2) time slots for TDMA, or (3) sub-bands for OFDM. A CDMA system may implement IS-2000, IS-95, IS-856, Wideband-CDMA (W-CDMA), or some other standards. An OFDM system may implement Institute of Electrical and Electronics Engineers (IEEE) 802.11, IEEE 802.16, Long Term Evolution (LTE) (e.g., in TDD and/or FDD modes), or some other standards. A TDMA system may implement Global System for Mobile Communications (GSM) or some other standards. These various standards are known in the art.

### An Example Wireless System

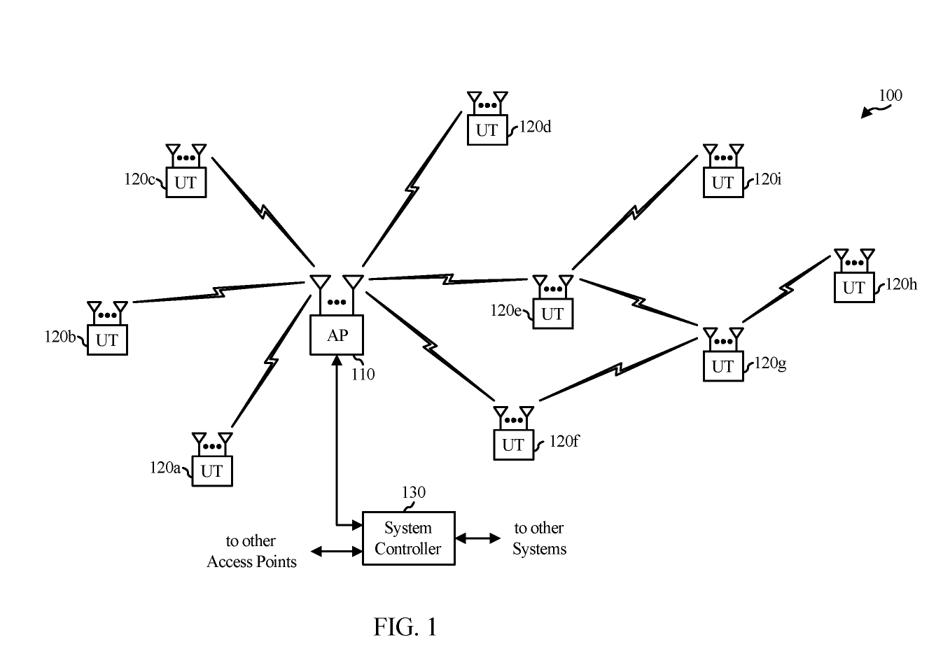

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

System 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless system 100 may be a time division duplex (TDD) system or a frequency division duplex (FDD) system. For a TDD system, the downlink and uplink share the same frequency band. For an FDD system, the downlink and uplink use different frequency bands. System 100 may also utilize a single carrier or multiple carriers for transmission. Each user terminal 120 may be equipped with a single antenna (e.g., in order to keep costs down) or multiple antennas (e.g., where the additional cost can be supported).

In certain aspects of the present disclosure, the access point 110 and/or user terminal 120 may include one or more mixers configured to receive local oscillator (LO) signals. In certain aspects, the LO signals may be generated using clock generation circuitry, as described in more detail herein.

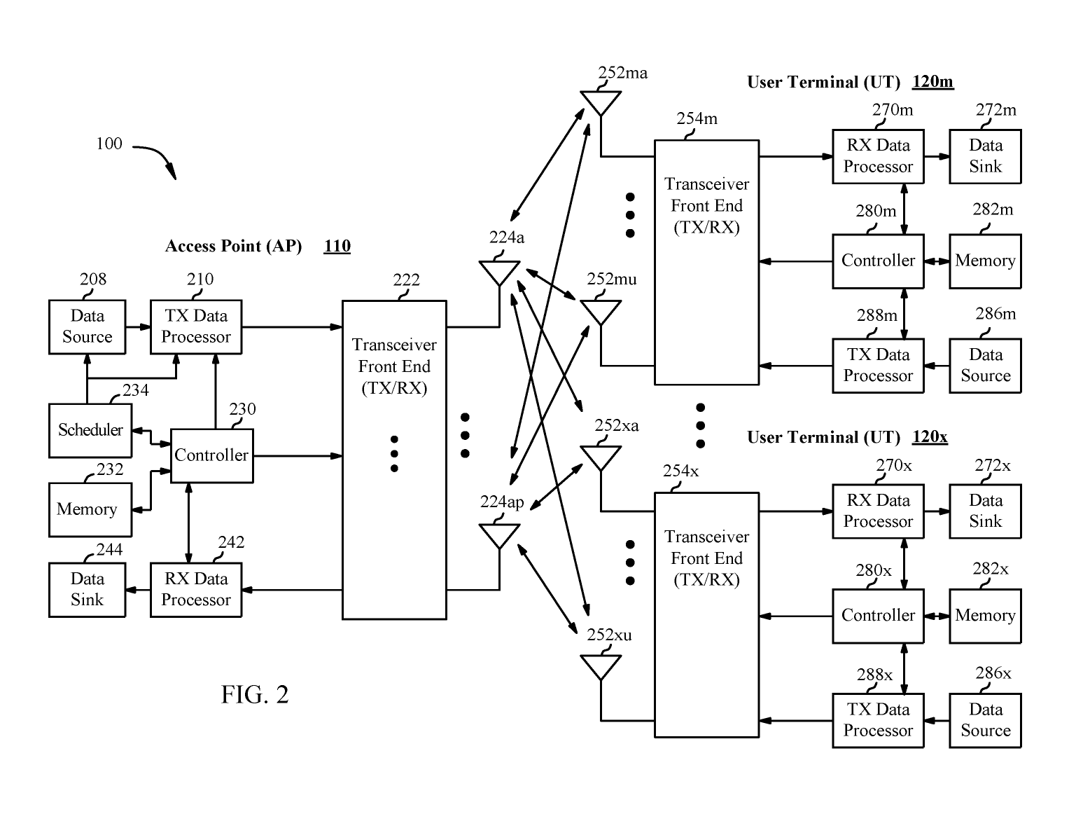

FIG. 2 shows a block diagram of access point 110 and two user terminals 120m and 120x in wireless system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering or some other spatial processing technique may be used at the access point and user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. The decoded data for each user terminal may be provided to a data sink 244 for storage and/or a controller 230 for further processing.

The transceiver front end (TX/RX) 222 of access point 110 and/or transceiver front end 254 of user terminal 120 may include one or more mixers configured to receive LO signals. In certain aspects, the LO signals may be generated using clock generation circuitry, as described in more detail herein.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal.

Those skilled in the art will recognize the techniques described herein may be generally applied in systems utilizing any type of multiple access schemes, such as TDMA, SDMA, Orthogonal Frequency Division Multiple Access (OFDMA), CDMA, SC-FDMA, TD-SCDMA, and combinations thereof

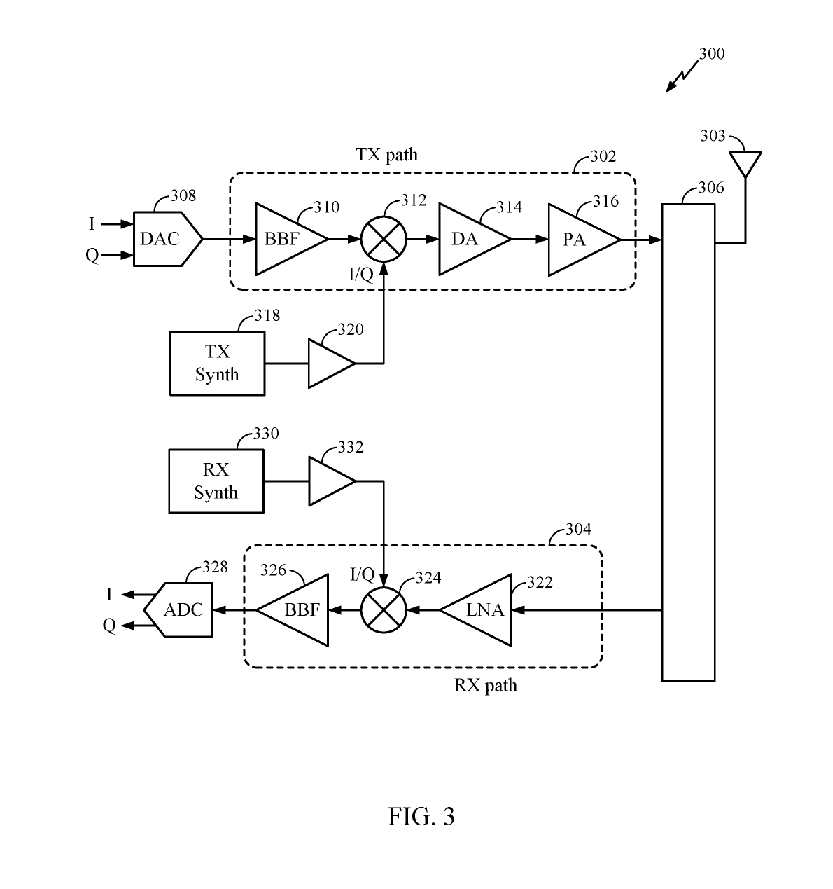

FIG. 3 is a block diagram of an example transceiver front end 300, such as transceiver front ends 222, 254 in FIG. 2, in which aspects of the present disclosure may be practiced. The transceiver front end 300 includes a transmit (TX) path 302 (also known as a transmit chain) for transmitting signals via one or more antennas and a receive (RX) path 304 (also known as a receive chain) for receiving signals via the antennas. When the TX path 302 and the RX path 304 share an antenna 303, the paths may be connected with the antenna via an interface 306, which may include any of various suitable RF devices, such as a duplexer, a switch, a diplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, and the DA 314 may be included in a radio frequency integrated circuit (RFIC), while the PA 316 may be external to the RFIC. The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency conversion process produces the sum and difference frequencies of the LO frequency and the frequency of the signal of interest. The sum and difference frequencies are referred to as the beat frequencies. The beat frequencies are typically in the RF range, such that the signals output by the mixer 312 are typically RF signals, which may be amplified by the DA 314 and/or by the PA 316 before transmission by the antenna 303.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I or Q signals for digital signal processing. In certain aspects, the LO signals received by mixers 312 and 324 may be generated using clock generation circuitry, as described in more detail herein.

While it is desirable for the output of an LO to remain stable in frequency, tuning to different frequencies indicates using a variable-frequency oscillator, which involves compromises between stability and tunability. Contemporary systems may employ frequency synthesizers with a voltage-controlled oscillator (VCO) to generate a stable, tunable LO with a particular tuning range. Thus, the transmit LO frequency may be produced by a TX frequency synthesizer 318, which may be buffered or amplified by amplifier 320 before being mixed with the baseband signals in the mixer 312. Similarly, the receive LO frequency may be produced by an RX frequency synthesizer 330, which may be buffered or amplified by amplifier 332 before being mixed with the RF signals in the mixer 324.

### Example Duty Cycle Control Buffer

Mixers for receivers and transmitters, such as the mixer 312 and mixer 324, may be implemented using a clock signal having a 25% duty cycle. The clock signal may be used as the local oscillator for mixers 312 and 324. In some cases, from the 25% duty cycle clock, non-overlapping clock signals, that may have a lower duty cycle such as 21%, may be generated for in-phase (I) and quadrature (Q) signals. In generating the 21% duty cycle clock signal, falling and/or rising edges of the 21% duty cycle clock signal may be degraded, and thus, a pull-up or pull-down network may experience increased noise and degraded phase noise. Certain aspects of the present disclosure are directed to generating non-overlapping clocks for in-phase (I) and quadrature (Q) signals from a 25% duty cycle clock with reduced degradation to the non-overlapping clock edges, thus improving phase noise performance.

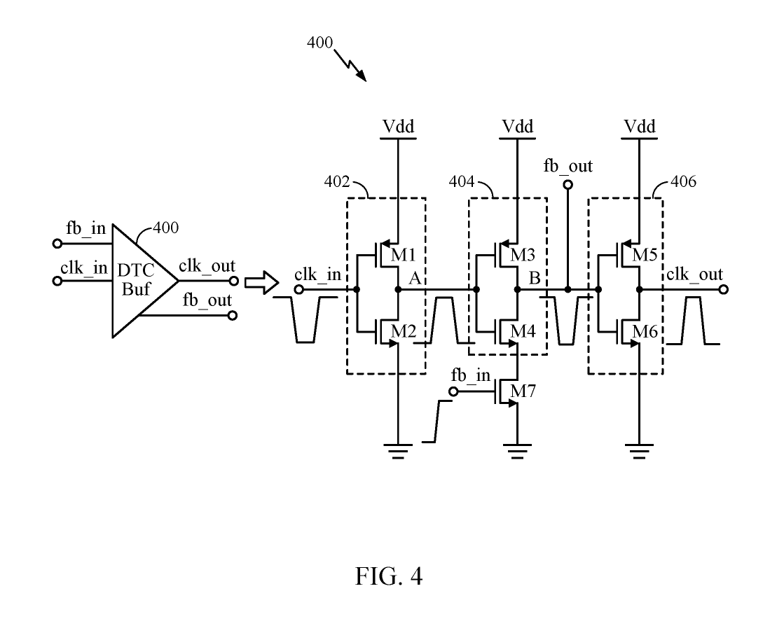

FIG. 4 illustrates an example duty cycle control (DTC) buffer stage 400, in accordance with certain aspects of the present disclosure. The DTC buffer stage 400 includes cascode-connected transistors M1 and M2 (composing an inverter 402) having drains coupled to gates of cascode-connected transistors M3 and M4 (composing an inverter 404). The drains of cascode-connected transistors M3 and M4 are coupled to gates of cascode-connected transistors M5 and M6 (composing an inverter 406). As illustrated, the transistors M1, M3, and M5 may be p-channel metal-oxide semiconductor (PMOS) transistors, and M2, M4, and M6 may be n-channel metal-oxide semiconductor (NMOS) transistors. An input clock signal (clk_in) is inverted after each inversion stage (i.e., after each inverter 402, 404, or 406) to generate an output clock signal (clk_out) that may have a lower duty cycle (e.g., 21%) than the duty cycle of the input clock signal (e.g., 25%).

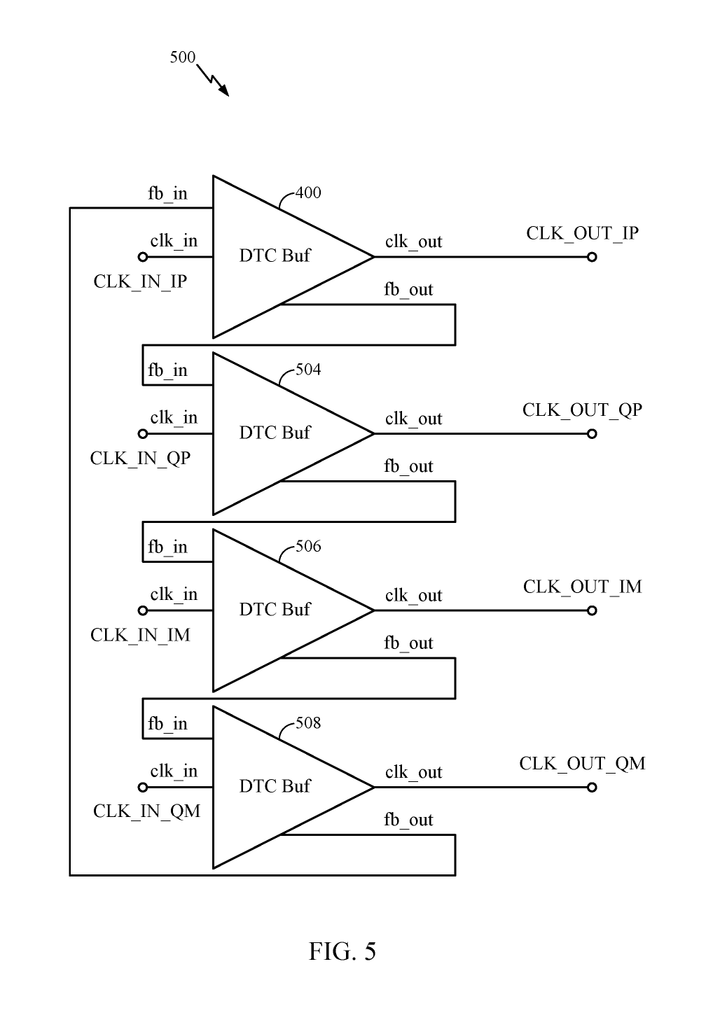

In certain aspects of the present disclosure, a transistor M7 may be coupled to the inverter 404. Specifically, a drain of transistor M7 may be coupled to the source of transistor M4. A gate of transistor M7 may be coupled to an input feedback signal (fb_in). As illustrated, transistor M7 is an NMOS transistor. Therefore, transistor M7 turns on when the signal fb_in goes high. Since transistor M7 is coupled between the inverter 404 and a reference potential (e.g., electrical ground), the inverter 404 is unable to pull the signal at node B down until transistor M7 closes. Therefore, it is only after fb_goes high that an output feedback signal (fb_out) at node B can go low (discharge). Therefore, with transistor M7, non-overlapping clock signals can be generated via multiple DTC buffers, as will be described in more detail with respect to FIG. 5.

FIG. 5 illustrates an example clock generation circuit 500 with multiple DTC buffer stages 400, 504, 506, and 508, in accordance with certain aspects of the present disclosure. The DTC buffer stages 400 and 506 receive a differential signal pair, CLK_IN_IP and CLK_IN_IM, and the DTC buffer stages 504 and 508 receive a differential signal pair, CLK_IN_QP and CLK_IN_QM. Thus, the DTC buffer stages 400 and 506 output a differential signal pair, CLK_OUT_IP and CLK_OUT_IM, and the DTC buffer stages 504 and 508 output a differential signal pair, CLK_OUT_QP and CLK_OUT_QM. For example, the DTC buffer stage 400 may generate a positive in-phase (I) output clock signal (CLK_OUT_IP), the DTC buffer stage 504 may generate a positive quadrature (Q) output clock signal (CLK_OUT_QP), the DTC buffer stage 506 may generate a negative in-phase (I) output clock signal (CLK_OUT_IM), and the DTC buffer stage 508 may generate a negative quadrature (Q) output clock signal (CLK_OUT_QM). Each of the DTC buffer stages 504, 506, 508 may be implemented using the circuit of the DTC buffer stage 400 of FIG. 4.

As illustrated, the signal fb_in for DTC buffer stage 504 is driven by the signal fb_out of DTC buffer 400. Therefore, only after the signal fb_out of DTC buffer stage 400 goes high (i.e., signal fb_in of DTC buffer stage 504 goes high), the signal fb_out of the DTC buffer stage 504 can go low. Therefore, only after the CLK_OUT_IP signal goes low can signal CLK_OUT_QP go high such that the signals CLK_OUT_IP and CLK_OUT_QP are non-overlapping.

Similarly, the fb_in signal of DTC buffer stage 506 is driven by the fb_out signal of DTC buffer stage 504, fb_in signal of the DTC buffer stage 508 is driven by the fb_out signal of the DTC buffer stage 506, and the fb_in signal of DTC buffer stage 400 is driven by the fb_out signal of DTC buffer stage 508. Thus, the DTC buffer stages 400, 504, 506, 508 generate non-overlapping signals CLK_OUT_IP, CLK_OUT_QP, CLK_OUT_IM, and CLK_OUT_QM. That is, the signal CLK_OUT_QP only goes high after CLK_OUT_IP goes low, signal CLK_out_IM only goes high after CLK_OUT_QP goes low, signal CLK_out_QM only goes high after CLK_OUT_IM goes low, and signal CLK_out_IP only goes high after CLK_OUT_QM goes low.

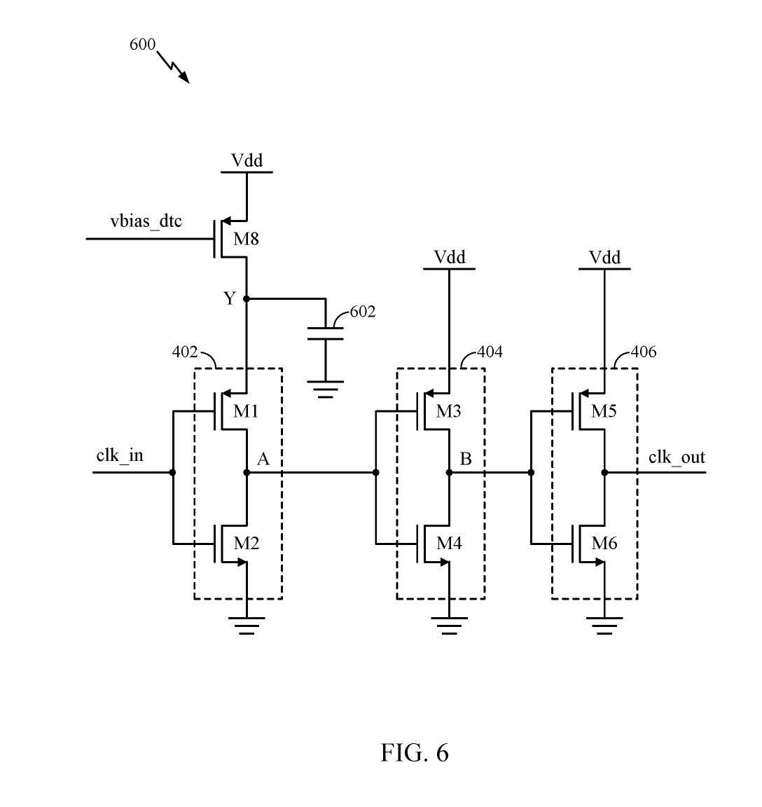

FIG. 6 illustrates a direct-current (DC) coupled DTC buffer stage 600, in accordance with certain aspects of the present disclosure. The DTC buffer stage 600 includes cascode-connected transistors M1 and M2 (inverter 402) having drains coupled to gates of cascode-connected transistors M3 and M4 (inverter 404). The drains of cascode-connected transistors M3 and M4 are coupled to gates of cascode-connected transistors M5 and M6 (inverter 406).

In certain aspects, a transistor M8 may be coupled to the inverter 402 (e.g., between the inverter 402 and voltage rail Vdd), and a capacitor 602 may be coupled between node Y and a reference potential. The transistor M7 may be biased in a triode region via a bias signal vbias_dtc. Therefore, any spikes in the current draw from transistor M1 to charge node A may be supplied by the capacitor 602. That is, since the current flow through M8 may be used to charge (recharge) the capacitor 602 that supplies power to charge node A, the current flow through transistor M8 may be a DC current that corresponds to the average of the current used to charge node A.

In certain aspects, the signal vbias_dtc may be used to adjust the duty cycle of the output clock signal (clk_out). For example, by increasing the voltage of the bias signal vbias_dtc, the triode resistance of the transistor M8 increases. Therefore, the voltage at node Y decreases (e.g., due to a voltage drop across the triode resistance of transistor M8), resulting in a reduction in the highest voltage level that node A can reach (e.g., when transistor M1 closes and node A goes high). The reduction in the highest voltage level that node A can reach results in a decrease in the slew rate of the signal at node B because the resistance of transistor M4 will be higher when closed. Thus, by adjusting the bias signal vbias_dtc, the slew rate at node B changes (e.g., degrades the falling edge of node B), resulting in a change of the duty cycle of the clk_out signal.

In certain aspects, the output clock signal clk_out may correspond to a positive in-phase (I) output clock signal (CLK_OUT_IP). Multiple other DTC buffer stages, each corresponding to the DTC buffer stage 600, may be implemented to generate a positive quadrature (Q) output clock signal (CLK_OUT_QP), a negative in-phase (I) output clock signal (CLK_OUT_IM), and a negative quadrature (Q) output clock signal (CLK_OUT_QM). The vbias_dtc signal for each of the DTC buffers for generating CLK_OUT_IP, CLK_OUT_QP, CLK_OUT_IM, and CLK_OUT_QM signals may be adjusted such that the CLK_OUT_IP, CLK_OUT_QP, CLK_OUT_IM, and CLK_OUT_QM signals are non-overlapping.

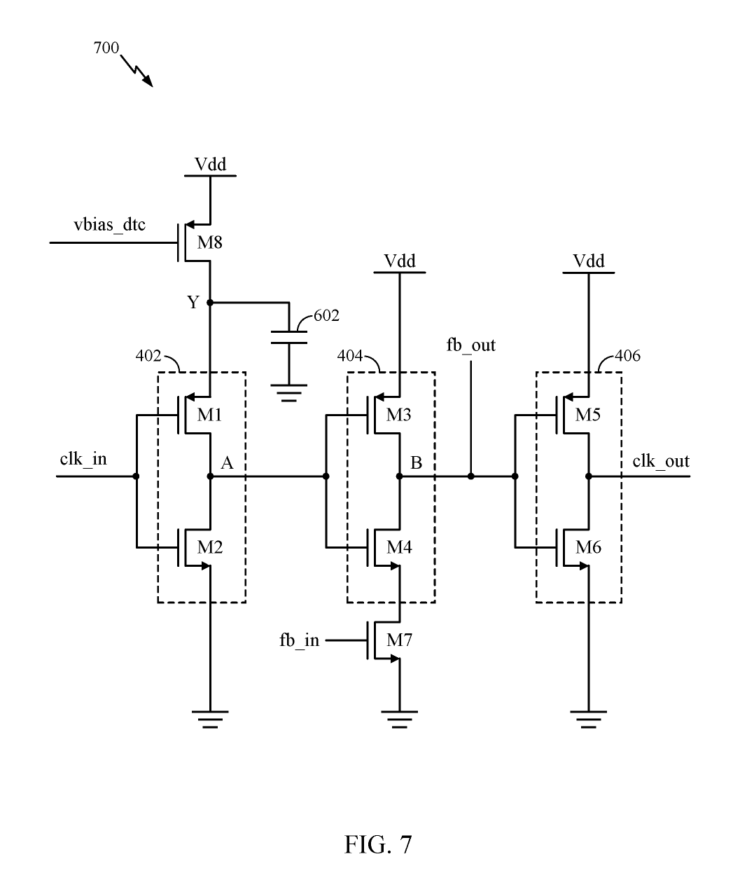

FIG. 7 illustrates a DTC buffer stage 700 combining the aspects of FIGS. 4 and 6, in accordance with certain aspects of the present disclosure. As illustrated, the DTC buffer stage 700 may include a transistor M7 coupled to the inverter 404 and a transistor M8 coupled to inverter 402. For example, at least one of the DTC buffer stages 400, 504, 506, and 508 of FIG. 5 may include the transistor M8 in addition to the transistor M7 such that the respective output clock signal of the DTC buffer stages 400, 504, 506, and 508 may be controlled via a respective vbias_dtc signal. By having both transistors M7 and M8, the DTC buffer stages 400, 504, 506, and 508 can generate non-overlapping clock signals as described with respect to FIGS. 4 and 5, and further, allow for control of the duty cycle of the non-overlapping clock signals as described with respect to FIG. 6.

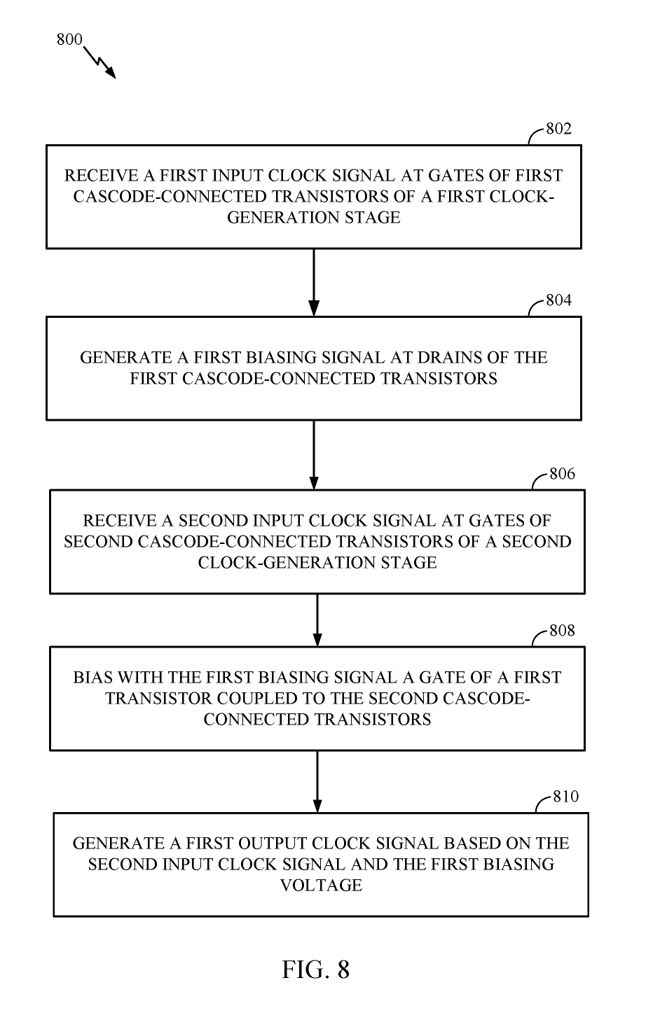

FIG. 8 is a flow diagram of example operations 800 for clock signal generation, in accordance with certain aspects of the present disclosure. The operations 800 may be performed by a circuit, such as the circuits of FIGS. 4 and 5.

The operations 800 begin at block 802 by receiving a first input clock signal (e.g., CLK_IN_QM) at gates of first cascode-connected transistors of a first clock-generation stage (e.g., DTC buffer stage 508), and at 804, generating a first biasing signal (e.g., fb_out signal output from DTC buffer stage 508) at drains of the first cascode-connected transistors. At block 806, the circuit may receive a second input clock signal (e.g., CLK_IN_IP) at gates of second cascode-connected transistors (e.g., inverter 404) of a second clock-generation stage (e.g., DTC buff 400), and at block 808, biasing with the first biasing signal a gate of a first transistor (e.g., transistor M7 of FIG. 4) coupled to the second cascode-connected transistors. At block 810, the operations 800 continue by generating a first output clock signal (e.g., CLK_OUT_IP) based on the second input clock signal and the first biasing signal.

In certain aspects, the operations 800 further include receiving a third input clock signal (e.g., CLK_IN_QP) at gates of third cascode-connected transistors of a third clock-generation stage (e.g., DTC buffer stage 504). In this case, a second biasing signal may be generated at drains of the second cascode-connected transistors and the second biasing signal may be used to bias a gate of a second transistor coupled to drains of the third cascode-connected transistors. A second output clock signal (e.g., CLK_OUT_QP) may be generated based on the third input clock signal and the second biasing signal.

In certain aspects, the operations 800 also include receiving a fourth input clock signal (e.g., CLK_IN_IM) at gates of fourth cascode-connected transistors. In this case, a third biasing signal may be generated at drains of the third cascode-connected transistors, and the third biasing circuit may be used to bias a gate of a third transistor coupled to the fourth cascode-connected transistors. A third output clock signal (e.g., CLK_OUT_IM) may be generated based on the fourth input clock signal and the third biasing signal.

In certain aspects, the operations 800 also include generating a fourth biasing signal at drains of the fourth cascode-connected transistors, and biasing with the fourth biasing signal a gate of a fourth transistor coupled to the first cascode-connected transistors. In this case, a fourth output clock signal (e.g., CLK_OUT_QM) may be generated based on the first input clock signal and the fourth biasing signal.

In certain aspects, the first input clock signal may correspond to a positive input signal of a first differential signal. The second input clock signal may correspond to a positive input signal of a second differential signal. The third input clock signal may correspond to a negative input signal of the first differential signal. The fourth input clock signal may correspond to a negative input signal of the second differential signal. In certain aspects, the first differential signal comprises an in-phase (I) signal, and the second differential signal comprises a quadrature (Q) signal.

In certain aspects, the operation 800 further include receiving a second biasing signal (e.g., vbias_dtc) at a gate of a second transistor (e.g., transistor M8 of FIG. 7) coupled to a third cascode-connected transistors (e.g., inverter 402), wherein drains of the third cascode-connected transistors are coupled to gates of the second cascode-connected transistors. In this case, a duty cycle of the first output clock signal may be controlled via the second biasing signal.

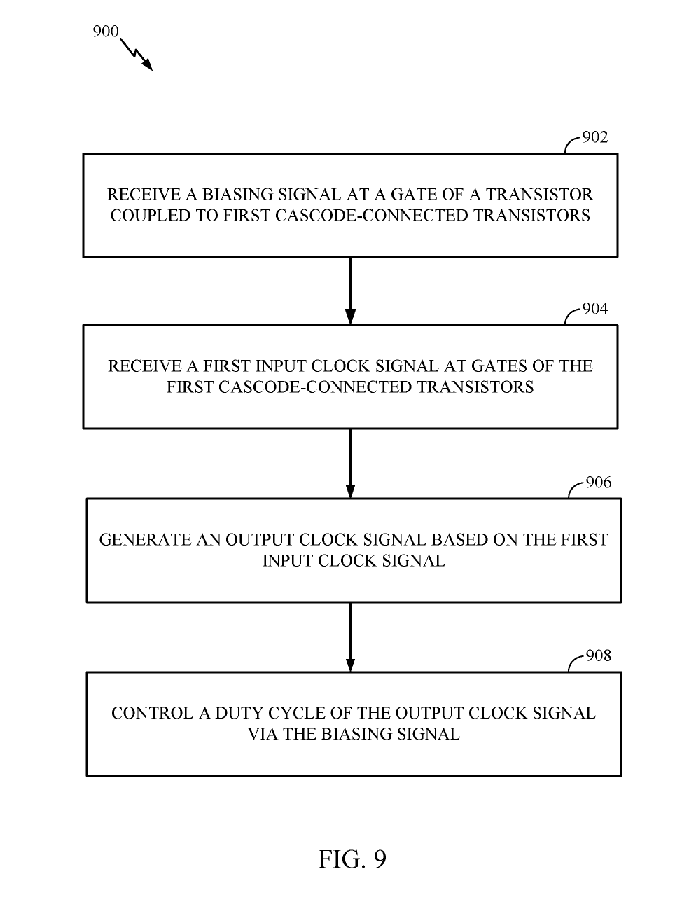

FIG. 9 is a flow diagram of example operations 900 for controlling a duty cycle of an output clock signal, in accordance with certain aspects of the present disclosure. The operations 900 may be performed by a circuit, such as the circuits of FIG. 6.

The operations 900 begin at block 902 by receiving a biasing signal (e.g., vbias_dtc of FIG. 6) at a gate of a transistor (e.g., transistor M8 of FIG. 6) coupled to first cascode-connected transistors (e.g., inverter 402 of FIG. 6), and at block 904, receiving an input clock signal (e.g., clk_in of FIG. 6) at gates of the first cascode-connected transistors. At block 906, the output clock signal (e.g., clk_out of FIG. 6) may be generated based on the input clock signal, and at block 908, the duty cycle of the output clock signal may be controlled via the biasing signal.

In certain aspects, the operations 900 also include generating a first signal (e.g., signal at node A of FIG. 6) at drains of the first cascode-connected transistors, receiving the first signal at gates of second cascode-connected transistors (e.g., inverter 404 of FIG. 6), generating a second signal at drains of the second cascode-connected transistors (e.g., signal at node B of FIG. 6), receiving the second signal at gates of third cascode-connected transistors (e.g., inverter 406 of FIG. 6), wherein generating the output clock signal comprises generating the output clock signal at drains of the third cascode-connected transistors. In certain aspects, the transistor may be biased, via the biasing signal, in a triode region.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the physical (PHY) layer. In the case of a user terminal, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC with the processor, the bus interface, the user interface in the case of an access terminal), supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes and variations may be made in the arrangement, operation and details of the methods and apparatus described above without departing from the scope of the claims.

1. A multi-stage clock-generation circuit comprising:
a first clock-generation stage comprising a first pair of transistors having drains that are coupled together, the first pair of transistors having gates coupled to a first input clock node; and
a second clock-generation stage comprising:
a second pair of transistors having drains that are coupled together, the second pair of transistors having gates coupled to a second input clock node; and
a first transistor coupled to at least one of the second pair of transistors, the first transistor having a gate coupled to the drains of the first pair of transistors.

2. The circuit of claim 1, wherein the second pair of transistors comprises a p-channel metal-oxide semiconductor (PMOS) transistor connected with an n-channel metal-oxide semiconductor (NMOS) transistor, and wherein the first transistor comprises another NMOS transistor having a drain coupled to a source of the NMOS transistor.

3. The circuit of claim 1, further comprising a third clock-generation stage comprising:
a third pair of transistors having drains that are coupled together, wherein gates of the third pair of transistors are coupled to a third input clock node; and
a second transistor coupled to at least one of the third pair of transistors, wherein a gate of the second transistor is coupled to the drains of the second pair of transistors.

4. The circuit of claim 3, wherein the first clock-generation stage further comprises a third transistor coupled to at least one of the first pair of transistors, the circuit further comprising a fourth clock-generation stage comprising:
a fourth pair of transistors having drains that are coupled together, wherein gates of the fourth pair of transistors are coupled to a fourth input clock node; and
a fourth transistor coupled to at least one of the fourth pair of transistors, wherein a gate of the fourth transistor is coupled to the drains of the third pair of transistors, and wherein a gate of the third transistor is coupled to the drains of the fourth pair of transistors.

5. The circuit of claim 4, wherein:
the first input clock node corresponds to a positive input node of a first differential node;
the second input clock node corresponds to a positive input node of a second differential node;
the third input clock node corresponds to a negative input node of the first differential node; and
the fourth input clock node corresponds to a negative input node of the second differential node.

6. The circuit of claim 5, wherein:
the first differential node is configured to receive an in-phase (I) signal; and
the second differential node is configured to receive a quadrature (Q) signal.

7. The circuit of claim 1, wherein the first clock-generation stage further comprises:
a third pair of transistors having drains that are coupled together, wherein gates of the third pair of transistors are coupled to the first input clock node, and wherein the drains of the third pair of transistors are coupled to the gates of the first pair of transistors; and
a fourth pair of transistors having drains that are coupled together, wherein gates of the fourth pair of transistors are coupled to the drains of the first pair of transistors, and wherein the drains of the fourth pair of transistors are coupled to a first output node of the circuit.

8. The circuit of claim 7, wherein the second clock-generation stage comprises:
a fifth pair of transistors having drains that are coupled together, wherein gates of the fifth pair of transistors are coupled to the second input clock node, and wherein the drains of the fifth pair of transistors are coupled to the gates of the second pair of transistors; and
a sixth pair of transistors having drains that are coupled together, wherein gates of the sixth pair of transistors are coupled to the drains of the second pair of transistors, and wherein the drains of the sixth pair of transistors are coupled to a second output node of the circuit.

9. The circuit of claim 1, further comprising:
a third pair of transistors having drains that are coupled together, wherein gates of the third pair of transistors are coupled to the second input clock node, and wherein the drains of the third pair of transistors are coupled to the gates of the second pair of transistors; and
a second transistor coupled to at least one of the third pair of transistors, wherein a biasing signal applied to a gate of the second transistor is configured to control a duty cycle of an output clock signal at an output node of the circuit.

10. The circuit of claim 9, wherein the second transistor is biased, via the biasing signal, in a triode region.

11. The circuit of claim 9, further comprising a capacitor coupled between a drain of the second transistor and a reference potential.

12. A duty-cycle control circuit comprising:
a first pair of transistors having drains that are coupled together and having gates coupled to a first input clock node;
a second pair of transistors having drains that are coupled together and having gates coupled to the drains of the first pair of transistors; and
a transistor coupled to at least one of the first pair of transistors.

13. The circuit of claim 12, wherein a biasing signal applied to a gate of the transistor is configured to control a duty cycle of an output clock signal at an output node of the circuit.

14. The circuit of claim 12, further comprising a third pair of transistors having drains that are coupled together, wherein gates of the third pair of transistors are coupled to the drains of the second pair of transistors, wherein the drains of the third pair of transistors are coupled to an output node of the circuit.

15. The circuit of claim 12, wherein the transistor is biased, via a biasing signal applied to a gate of the transistor, in a triode region.

16. The circuit of claim 12, wherein a source of the transistor is coupled to a voltage rail and wherein a drain of the transistor is coupled to a source of a p-channel metal-oxide semiconductor (PMOS) transistor of the first pair of transistors.

17. The circuit of claim 16, wherein a source of an n-channel metal-oxide semiconductor (NMOS) transistor of the first pair of transistors is coupled to a reference potential and wherein the drain of the NMOS transistor is coupled to the drain of the PMOS transistor.

18. The circuit of claim 17, wherein the second pair of transistors are coupled between the voltage rail and the reference potential.

19. The circuit of claim 12, further comprising a capacitor coupled between a drain of the transistor and a reference potential.

20. A method for clock signal generation, comprising:
receiving a first input clock signal at gates of a first pair of transistors of a first clock-generation stage;
generating a first biasing signal at drains of the first pair of transistors;
receiving a second input clock signal at gates of a second pair of transistors of a second clock-generation stage;
biasing with the first biasing signal a gate of a first transistor coupled to at least one of the second pair of transistors; and
generating a first output clock signal based on the second input clock signal and the first biasing signal.

21. The method of claim 20, further comprising:
receiving a third input clock signal at gates of a third pair of transistors of a third clock-generation stage;
generating a second biasing signal at drains of the second pair of transistors;
biasing with the second biasing signal a gate of a second transistor coupled to a drain of at least one of the third pair of transistors; and
generating a second output clock signal based on the third input clock signal and the second biasing signal.

22. The method of claim 21, further comprising:
receiving a fourth input clock signal at gates of a fourth pair of transistors;
generating a third biasing signal at drains of the third pair of transistors;
biasing with the third biasing signal a gate of a third transistor coupled to the fourth pair of transistors; and
generating a third output clock signal based on the fourth input clock signal and the third biasing signal.

23. The method of claim 22, further comprising:
generating a fourth biasing signal at drains of the fourth pair of transistors;
biasing, with the fourth biasing signal, a gate of a fourth transistor coupled to at least one of the first pair of transistors; and
generating a fourth output clock signal based on the first input clock signal and the fourth biasing signal.

24. The method of claim 23, wherein:
the first input clock signal corresponds to a positive input signal of a first differential signal;
the second input clock signal corresponds to a positive input signal of a second differential signal;
the third input clock signal corresponds to a negative input signal of the first differential signal; and
the fourth input clock signal corresponds to a negative input signal of the second differential signal.

25. The method of claim 24, wherein:
the first differential signal comprises an in-phase (I) signal; and
the second differential signal comprises a quadrature (Q) signal.

26. The method of claim 20, further comprising:
receiving a second biasing signal at a gate of a second transistor coupled to a third pair of transistors, wherein drains of the third pair of transistors are coupled to gates of the second pair of transistors; and
controlling a duty cycle of the first output clock signal via the second biasing signal.

27. The method of claim 26, wherein the second transistor is biased, via the second biasing signal, in a triode region.

28. A method for controlling a duty cycle of an output clock signal, comprising:
receiving a biasing signal at a gate of a transistor coupled to at least one of a first pair of transistors;
receiving an input clock signal at gates of the first pair of transistors;
generating the output clock signal based on the input clock signal; and
controlling the duty cycle of the output clock signal via the biasing signal.

29. The method of claim 28, wherein the transistor is biased, via the biasing signal, in a triode region.

30. The method of claim 28, further comprising:
generating a first signal at drains of the first pair of transistors;
receiving the first signal at gates of a second pair of transistors;
generating a second signal at drains of the second pair of transistors;
receiving the second signal at gates of a third pair of transistors,
wherein generating the output clock signal comprises generating the output clock signal at drains of the third pair of transistors.
